(19) United States
(12) Patent Application Publication
(10) Pub. No.: US 2017/0098691 A1
(43) Pub. Date: Apr. 6, 2017

(54) METHOD FOR MANUFACTURING AN INTEGRATED CIRCUIT

(71) Applicant: VIMICRO CORPORATION, Beijing (CN)

(72) Inventors: Zhao Wang, Beijing (CN); Wenbo Tian, Beijing (CN); Hang Yin, Beijing (CN)

(21) Appl. No.: 15/251,881

(22) Filed: Aug. 30, 2016

Related U.S. Application Data
(63) Continuation-in-part of application No. 13/311,115, filed on Dec. 5, 2011, now abandoned.
Application No. 13/311,115 is a continuation of application No. PCT/CN2010/073729, filed on Jun. 9, 2010.

(30) Foreign Application Priority Data
Jun. 10, 2009 (CN) 200910086878.0

(51) Int. Cl. H01L 49/02; H01L 21/8249; H01L 21/8222; H01L 27/06; H01L 21/8234

(52) U.S. Cl. CPC H01L 28/20; H01L 27/0629; H01L 27/0647; H01L 21/823493; H01L 21/8222; H01L 21/8249; H01L 27/0623

(57) ABSTRACT

Techniques related to a method for manufacturing an integrated circuit is disclosed. According to one embodiment, a method for manufacturing an integrated circuit on a wafer comprises a first device of the integrated circuit is formed on the wafer and a second device of the integrated circuit is formed on the wafer to make a projection area of the second device overlap with a projection area of the first device partially or completely. In one embodiment, two or more devices are formed in different layers of the integrated circuit, or formed at different depths in a same layer of the integrated circuit, so the two or more devices may share an area on the same wafer in a certain manner. Thereby, the area of the chip is saved and the chip cost of the integrated circuit is significantly reduced.

### CROSS-REFERENCE TO RELATED APPLICATION

This application is a continuation in part of U.S. patent application Ser. No. 13/311,115, filed on Dec. 5, 2011, which is a continuation application of PCT/CN2010/073729 (filed on Jun. 9, 2010), which claims priority from CN Patent Application Serial No. 200910086878.0, filed on Jun. 10, 2009, the entire contents of which are incorporated herein by reference for all purposes.

### FIELD OF THE INVENTION

The invention is related to the area of integrated circuits, particularly to a method for manufacturing an integrated circuit.

### BACKGROUND OF THE INVENTION

Most of conventional integrated circuits are 2D (two-dimensional) integrated circuits in planar process. Device units in the 2D integrated circuit are distributed on the same plane. Therefore, the 2D integrated circuit not only has a limited operating speed, but also occupies much more chip area.

A 3D (three-dimensional) integrated circuit is developed to improve the integration level and the operating speed of the integrated circuits. The 3D integrated circuit is sometimes called as stereo integrated circuit, which is an integrated circuit having a multilayer overlapping structure. Evidently, the integration level of a 3D integrated circuit is multiplied compared to the conventional 2D IC structure.

In the prior art, realizing the 3D integrated circuit is generally to form circuits on different wafers by photo-etching and then to connect the different wafers together through a special process. Such technique has a relatively complex process and higher cost.

Silicon wafers come in different sizes such as 4, 6, 8 and 12 inches, wherein the size in inch is a diameter of a wafer. The wafer area is invariable for the production line of a certain process. The cost of each single chip is determined by its chip area in the case of identical photoetching steps. Thus the smaller a chip area is, the more the number of the chips can be produced from a wafer, thus the lower the cost of a chip is. Moreover, the smaller the area of each single chip is, the higher a yield of the chips on the wafers is, and thus the more effective chips can be produced from a wafer.

Therefore, improved techniques for 3D integrated circuits are desired to solve at least the above problems.

### SUMMARY OF THE INVENTION

This section is for the purpose of summarizing some aspects of the present invention and to briefly introduce some preferred embodiments. Simplifications or omissions in this section as well as in the abstract or the title of this description may be made to avoid obscuring the purpose of this section, the abstract and the title. Such simplifications or omissions are not intended to limit the scope of the present invention.

In general, the present invention is related to 3D integrated circuits formed on a single wafer and a method for manufacturing a 3D integrated circuit. According to one aspect of the present invention, an integrated circuit comprises a first device forming a first projection area on a wafer and a second device forming a second projection area on the wafer. The first projection area overlaps with the second projection area partially or completely. According to one aspect of the present invention, a method for manufacturing an integrated circuit on a wafer comprises a first device of the integrated circuit is formed on the wafer and a second device of the integrated circuit is formed on the wafer to make a projection area of the second device overlap with a projection area of the first device partially or completely. The area being shared between the two devices refers to the partial or complete overlapping of the projection areas of the two devices.

According to an aspect of the present invention, two or more devices in different layers of the integrated circuit or two or more devices at different depths in a same layer of the integrated circuit may share an area on the same wafer in a certain manner. Thereby, the area of the chip is saved and the chip cost of the integrated circuit is significantly reduced.

There are many objects, features, and advantages in the present invention, they will become apparent upon examining the following detailed description of an embodiment thereof, taken in conjunction with the attached drawings.

### BRIEF DESCRIPTION OF THE DRAWINGS

These and other features, aspects, and advantages of the present invention will become better understood with regard to the following description, appended claims, and accompanying drawings where:

FIG. 1 is a schematic diagram showing an area being shared between a Poly resistor and an Nwell resistor matching with the Poly resistor according to one embodiment of the present invention;

FIG. 2 is a schematic diagram showing an area being shared between the Poly resistor and the Nwell resistor mismatching with the Poly resistor according to one embodiment of the present invention;

FIG. 3 is a circuit diagram showing a bias current generation circuit;

FIG. 4 is a sectional view showing the area shared between a P+ resistor and the Nwell resistor according to one embodiment of the present invention;

FIG. 5 is a sectional view showing the area shared between the Poly resistor and an NMOS transistor according to one embodiment of the present invention;

FIG. 6 is a sectional view showing the area shared between the Poly resistor and a PMOS transistor according to one embodiment of the present invention;

FIG. 7 shows a snakelike NMOS transistor in an inverse width-to-length ratio;

FIG. 8 is a schematic diagram showing the area shared between the Poly resistor and the NMOS transistor according to one embodiment of the present invention;

FIG. 9 is a circuit diagram showing another bias current generation circuit;

FIG. 10 is a sectional view showing the area shared between the Nwell resistor and the NMOS transistor according to one embodiment of the present invention;

FIG. 11 is a sectional view showing the area shared between a Pwell resistor and the PMOS resistor according to one embodiment of the present invention;

FIG. 12 is a sectional view showing the area shared between the NMOS transistor and a PNP bipolar transistor according to one embodiment of the present invention;

FIG. 13 is a sectional view showing the area shared between the PMOS transistor and an NPN bipolar transistor according to one embodiment of the present invention;

FIG. 14 is a schematic diagram showing the area shared between a trimming unit and a capacitor according to one embodiment of the present invention;

FIG. 15 is a flow chart of a method for manufacturing an integrated circuit provided in an embodiment of the present invention;

FIG. 16 is a flow chart of a method for manufacturing an integrated circuit provided in another embodiment of the present invention;

FIG. 17 is a flow chart of a method for manufacturing an integrated circuit provided in another embodiment of the present invention; and

FIG. 18 is a flow chart of a method for manufacturing an integrated circuit provided in another embodiment of the present invention.

### DETAILED DESCRIPTION OF THE INVENTION

The detailed description of the present invention is presented largely in terms of procedures, steps, logic blocks, processing, or other symbolic representations that directly or indirectly resemble the operations of devices or systems contemplated in the present invention. These descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams or the use of sequence numbers representing one or more embodiments of the invention do not inherently indicate any particular order nor imply any limitations in the invention.

Embodiments of an integrated circuit provided by the present invention are discussed herein with reference to FIGS. 1-14. However, those skilled in the art will readily appreciate that the detailed description given herein with respect to these figures is for explanatory purposes only as the invention extends beyond these embodiments.

In general, an integrated circuit consists of a plurality of layers. In one embodiment, an N+ resistor, a P+ resistor, an Nwell (N-type well) resistor, a Pwell (P-type well) resistor, an N+ area and a P+ area of a bipolar transistor (e.g., an NPN bipolar transistor or a PNP bipolar transistor) and a MOS (Metal Oxide Semiconductor) transistor (e.g. an NMOS transistor and a PMOS transistor) are formed on a first layer which is the lowest layer. A Poly (polysilicon) area of a gate of the MOS transistor is formed on a second layer above the first layer. A Poly resistor is formed on a third layer above the second layer. In general, the Poly resistor is formed by a second polysilicon (Poly2) having higher resistance, while the Poly area forming the gate of the MOS transistor is formed by a first polysilicon (poly1) having lower resistance. The first polysilicon and the second polysilicon have different definitions in different process production lines. Other devices in the integrated circuit such as capacitor, inductor and the like are formed on a fourth layer above the third layer. A trimming circuit or a metal resistor is formed on an uppermost fifth layer which is the highest layer.

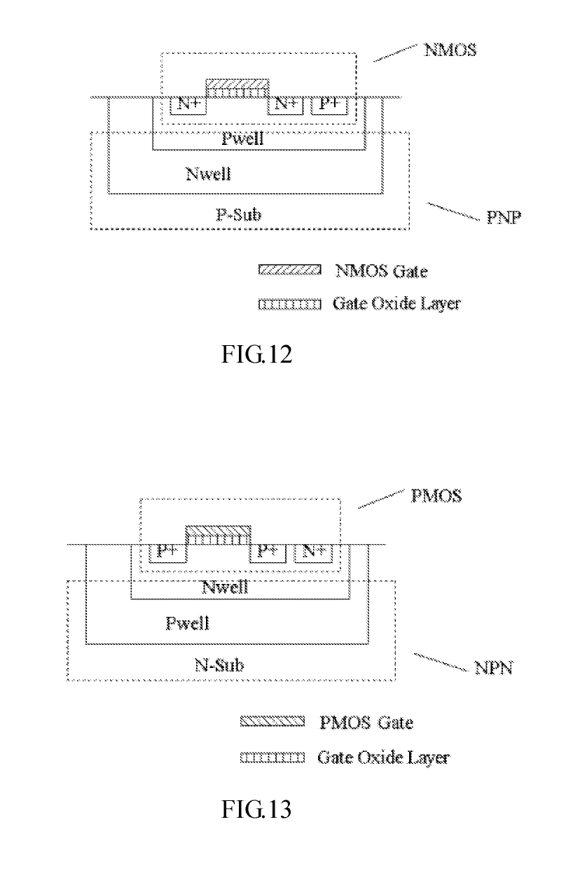

Some devices in the first layer are located at the same depth, and some devices in the first layer are located at different depth. Referring to FIG. 12 and FIG. 13, the N+ resistor, the P+ resistor, the N+ area and the P+ area of the MOS transistor are located at the same depth of the first layer. However, the Pwell resistor is deeper than the N+ resistor, the Nwell resistor is deeper than the Pwell resistor, and a P-substrate or an N-substrate of the MOS transistor is the deepest.

Based on above description, it can be seen that the most of devices, such as the N+ resistor, the P+ resistor, the Nwell resistor, the Pwell resistor, the Poly resistor, the trimming circuit, the metal resistor and so on, of the integrated circuit are located in one layer of the plural layers of the integrated circuit. However, the MOS transistor is located in two layers of the plural layers of the integrated circuit. Specifically, the Poly area of the MOS transistor is in the second layer of the plural layers of the integrated circuit, and the N+ area and P+ area of the MOS transistor are located in the first layer of the plural layers of the integrated circuit.

In the present invention, two or more devices in different layers of the integrated circuit or two or more devices at different depths in the same layer of the integrated circuit may share an area on the same wafer by a certain manner. Thereby, the area of the chip is saved and the chip cost of the integrated circuit is reduced significantly.

Generally speaking, the present invention is related to a 3D integrated circuit formed on the same wafer. The integrated circuit comprises a first device forming a first projection area on the wafer and a second device forming a second projection area on the wafer. The first projection area overlaps with the second projection area partially or completely. In one embodiment, an area shared between the two devices refers to the partial or complete overlapping of the projection areas of the two devices.

The area sharing structure between the devices in different layers and the area sharing structure between the devices at different depths in the same layer are illustrated hereafter.

I. Area Shared Between Resistors in Different Layers

The Poly resistor and the Nwell resistor are located in different layers. Therefore, the Poly resistor and the Nwell resistor can share an area on the wafer. The Poly resistor and the Nwell resistor may be matched with each other, and also may be mismatched with each other. When the Poly resistor is required to be matched with the Nwell resistor, a position relationship of the area shared between the Poly resistor and the Nwell resistor may be shown as FIG. 1.

FIG. 1 is a schematic diagram showing the area being shared between the Poly resistor and the Nwell resistor matching with the Poly resistor according to one embodiment of the present invention. Referring to FIG. 1, the Poly resistor is placed in segments with the same width, the same length and the same interval. The Nwell resistor is also placed in segments with the same width, the same length and the same interval. In other words, when the system has high requirement for a matching degree between the two types of resistors, the same type of the resistor shall be placed in segments orderly and keep the same interval between the segments. In a preferred embodiment, the matching degree can be further improved by drawing a dummy device between the resistor segments.

The reason for placing the same type of the resistor segments orderly is that etching or diffusion is a very important factor affecting the width and the length of the device during the device forming process. These technical processes are related with the surrounding environment. The matching degree of the resistor will be affected adversely if the same type of the resistor segments doesn't be placed orderly. Taking the Poly resistor as an example, an edge of the Poly resistor with larger intervals is etched more quickly, while the edge of the Poly resistor with smaller intervals is etched more slowly. Therefore, the Poly resistor shall be placed in segments with the same interval in order to achieve the same etching speed, thereby improving the matching degree of the Poly resistor.

In a preferred embodiment, the Poly resistor segments are located between two adjacent Nwell resistor segments, thereby improving the matching degree between the Poly resistor and the Nwell resistor. In a further preferred embodiment, the Poly resistor segments are located in the middle of two adjacent Nwell resistor segments, thereby further improving the matching degree between the Poly resistor and the Nwell resistor. It should be noted that although the Poly resistor segments are located between the two adjacent Nwell resistor segments for the single resistor segment, and the projection of the single Poly resistor segment don't overlap with the projection of the single Nwell resistor segment. However, the projection of the Poly resistor as a whole overlaps with the projection of the Nwell resistor as a whole.

Preferably, a flow direction of a current in each resistor segment is identical, thereby further improving the matching degree between the Poly resistor and the Nwell resistor.

FIG. 1 schematically shows the position relationship between the Poly resistor and the Nwell resistor. Actually, the Poly resistor and the Nwell resistor are not located in the same plane and the Poly resistor is located above the Nwell resistor. Thus, the area shared between the Poly resistor and the Nwell resistor can be realized to reduce the chip area. Referring to FIG. 1, the Poly resistor is not limited to be located in the middle of the Nwell resistor and can also be located in any position above the Nwell resistor. The Poly resistor and the Nwell resistor have the highest matching degree when the Poly resistor is located in the middle of the Nwell resistor. The order of the matching degree between the Poly resistor and the Nwell resistor from lower to higher is that: the Poly resistor is located above the Nwell resistor, the Poly resistor segment is located between the adjacent Nwell resistor segments, and the Poly resistor segment is located in the middle of the adjacent Nwell resistor segments.

Furthermore, the Poly resistor segment is located between the adjacent Nwell resistor segments that can further save space and reduce the chip area. In general, the interval and the width of the Nwell resistor are bigger than that of the Poly resistor in manufacture process. For example, the minimum interval of the Nwell resistor is 4 um, the minimum width of the Nwell resistor is 4 um, the minimum interval of the Poly resistor is 1 um, and the minimum width of the Poly resistor is 0.8 um. Hence, the Poly resistor and the Nwell resistor have no mutual effect when the Poly resistor segments are placed between the Nwell resistor segments.

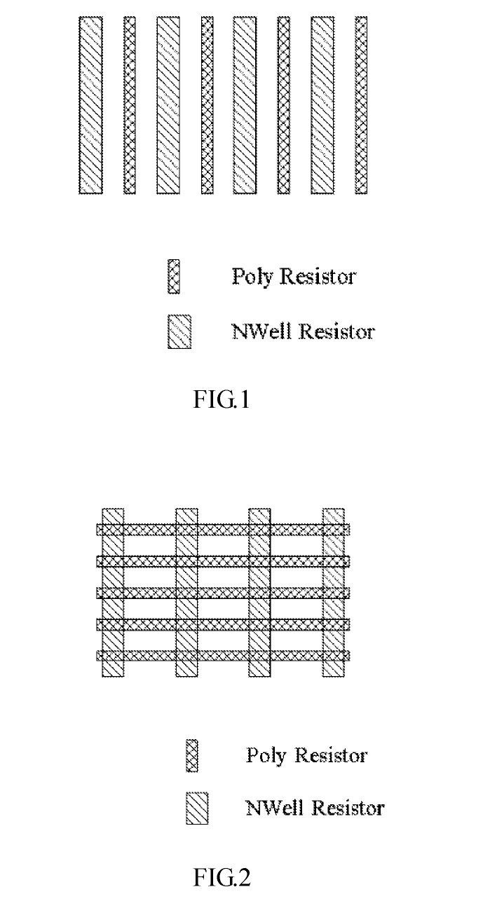

When the Poly resistor is not required to be matched with the Nwell resistor, a position relationship of the area shared between the Poly resistor and the Nwell resistor may be shown as FIG. 2. FIG. 2 is a schematic diagram showing the area shared between the Poly resistor and the Nwell resistor mismatching with the Poly resistor according to one embodiment of the present invention. FIG. 2 schematically shows the position relationship between the Poly resistor and the Nwell resistor. Actually, the Poly resistor and the Nwell resistor are not located in the same plane and the Poly resistor is located above the Nwell resistor. Thus, the area shared between the Poly resistor and the Nwell resistor can be realized to reduce the chip area. In general, the Poly resistor and the Nwell resistor are vertical to each other as shown in FIG. 2. However, the Poly resistor also may be placed to be not vertical to the Nwell resistor in some embodiments.

Placing the Poly resistor and the Nwell resistor in different directions may lead to unevenness of a field oxide layer of the Nwell resistor, thereby further leading to unevenness of the Poly resistor deposited on the field oxide layer. Furthermore, a parasitic capacitance may be generated between different resistors sometimes, thereby causing noise or affecting a stability of a loop circuit and so on.

The area shared between resistors in different layers is described by taking the Poly resistor and the Nwell resistor as an example in the forgoing paragraph. Actually, the area shared is not limited to the Poly resistor and the Nwell resistor, and any two or more resistors in different layers can share an area. The Poly resistor, the metal resistor and anyone of the Nwell resistor, the N+ resistor, the Pwell resistor and the P+ resistor are not located in the same layer, thereby these resistors in different layers can share an area. The Poly resistor comprises a first polysilicon (Poly1) resistor and a second Polysilicon (Poly2) resistor. The Poly1 resistor and the Poly2 resistor are located in different layers; thereby the Poly1 resistor and the Poly2 resistor can share an area. Furthermore, one or more of the Poly1 resistor, the Poly2 resistor and the metal resistor and anyone of the Nwell resistor, the N+ resistor, the Pwell resistor and the P+ resistor can share an area to save the chip area.

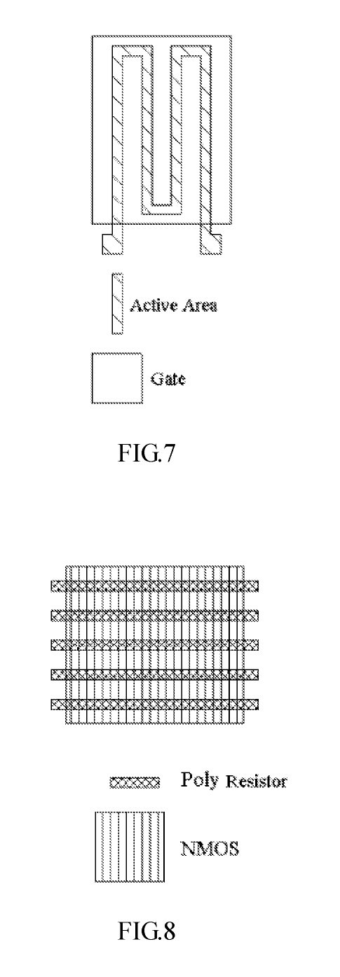

It should be noted that the Poly resistor and the Nwell resistor may not emerge in the form of resistor segments as shown in FIG. 1 and FIG. 2. Actually, the Poly resistor and the Nwell resistor may also be a sinuous snakelike design as an active area of an NMOS transistor shown in FIG. 7. Meanwhile, the N+ resistor, the Pwell resistor and the P+ resistor can also be in the form of resistor segments or the snakelike design.

The area sharing structure of the Poly resistor and the Nwell resistor is further described by taking a specific application circuit as an example hereafter.

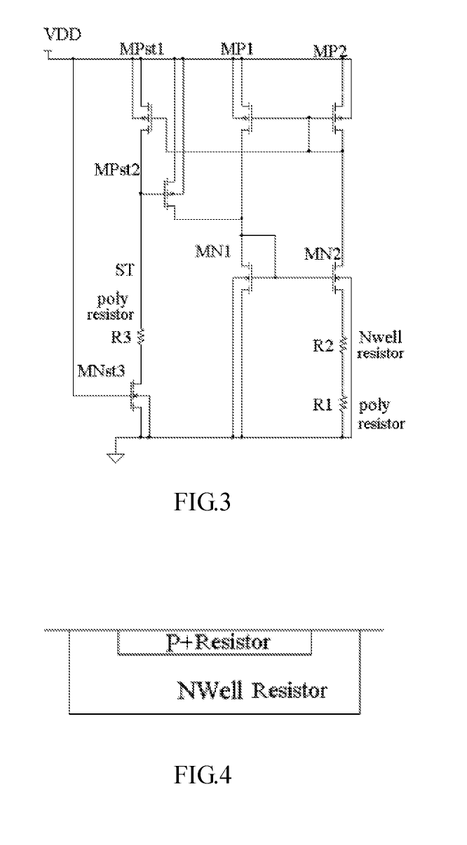

FIG. 3 is a circuit diagram showing a bias current generation circuit. One difference between the bias current generation circuit shown in FIG. 3 and a conventional bias current generation circuit is that a resistor R1 and a resistor R2 adopt an area sharing structure between the Poly resistor and the Nwell resistor.

An output current of a circuit is affected directly because a temperature of the circuit rises after the circuit is electrified. Hence, the temperature coefficient of the output current shall be compensated frequently. One compensation method is to use two resistors with different temperature coefficient in the circuit. The Poly resistor and the Nwell resistor have inverse temperature coefficients. Therefore, the resistor R1 shown in FIG. 3 uses the Poly resistor, and the resistor R2 shown in FIG. 3 uses the Nwell resistor. Thus, the temperature coefficient of the output current shall be compensated perfectly by using the resistors with inverse temperature coefficients. For saving the chip area, the resistor R1 and the resistor R2 can share an area on the same wafer in a layout design. In other embodiments, the resistor R2 can also use the N+ resistor, the Pwell resistor and the P+ resistor having the same temperature coefficient with the Nwell resistor.

II. Area Shared Between Resistors at Different Depths in the First Layer

The P+ resistor and the N+ resistor are located at the same depth in the first layer, so they cannot share an area. The Pwell resistor and the P+ resistor belong to the same type (P type), so they cannot share an area although they are located at different depths. The Nwell resistor and the N+ resistor belong to the same type (N type), so they cannot share an area although they are located at different depths. The P type resistor is nonconductive with the N type resistor when a highest potential of the P type resistor is lower than a lowest potential of the N type resistor. Hence, the P type resistor and the N type resistor at different depths can share an area when the highest potential of the P type resistor is lower than the lowest potential of the N type resistor.

FIG. 4 is a sectional view showing the area shared between the P+ resistor and the Nwell resistor. The P+ resistor and the Nwell resistor are located in the same layer but at different depths. The P+ resistor is nonconductive with the Nwell resistor when the highest potential of the P+ resistor is lower than the lowest potential of the Nwell resistor. Hence, the P+ resistor can share an area with the Nwell resistor as shown in FIG. 4.

III. Area Shared Between the Poly Resistor and the MOS Transistor

The MOS transistor comprises an NMOS (N-channel metal oxide semiconductor) transistor and a PMOS (P-channel metal oxide semiconductor) transistor. The MOS transistor operated in a linear area is equivalent to a resistor, so one resistor locating in a different layer with the MOS transistor can share an area with the MOS transistor.

FIG. 5 is a sectional view showing the area shared between the Poly resistor and the NMOS transistor. A gate of the NMOS transistor is formed by a Poly1 area, a source and a drain of the NMOS transistor are formed by two N+ areas respectively, and a substrate of the NMOS transistor is formed by a P+ area. A gate oxide layer is formed below the gate of the NMOS transistor. A P type area with lower concentration is formed between the source and the drain of the NMOS transistor (not shown). In general, the P type area with lower concentration is P− or Pwell. The substrate of the NMOS transistor is provided to connect the NMOS transistor to a ground (VSS) or a power supply (VDD). A field oxide layer is formed between the gate of the NMOS transistor and the Poly resistor for insulation.

Referring to FIG. 5, the Poly resistor can share an area with the NMOS transistor because the Poly resistor and the gate of the NMOS transistor are not located in the same layer. Furthermore, the Poly resistor is not located in the same layer with the source, the drain and the substrate of the NMOS transistor as well.

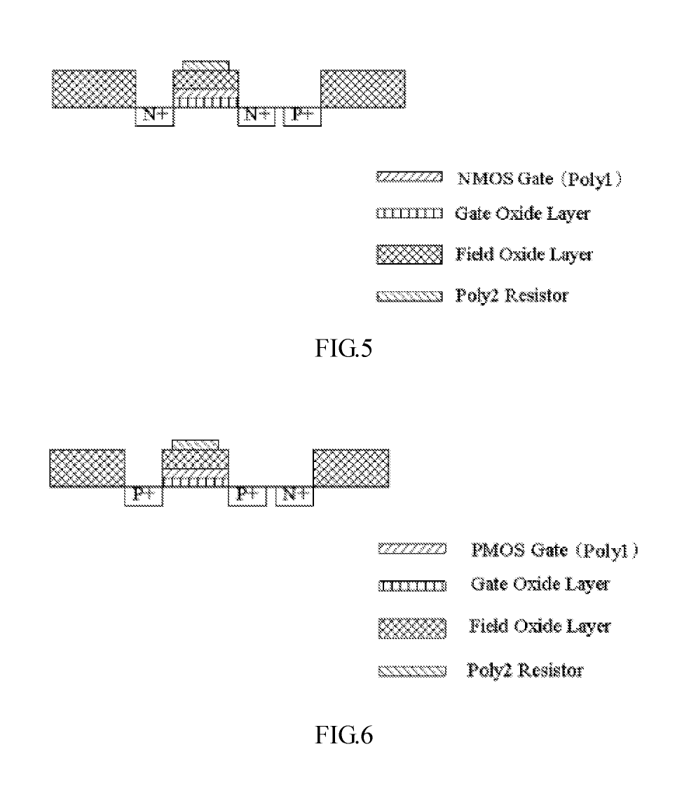

FIG. 6 is a sectional view showing the area shared between the Poly resistor and the PMOS transistor. A gate of the PMOS transistor is formed by a Poly1 area, a source and a drain of the PMOS transistor are formed by two P+ areas respectively, and a substrate of the PMOS transistor is formed by an N+ area. A gate oxide layer is formed below the gate of the PMOS transistor. An N type area with lower concentration is formed between the source and the drain of the PMOS transistor (not shown). In general, the N type area with lower concentration is N- or Nwell. The substrate of the PMOS transistor is provided to connect the PMOS transistor to a ground (VSS) or a power supply (VDD). A field oxide layer is formed between the gate of the PMOS transistor and the Poly resistor for insulation.

Referring to FIG. 6, the Poly resistor can share an area with the PMOS transistor because the Poly resistor and the gate of the PMOS transistor are not located in the same layer. Furthermore, the Poly resistor is not located in the same layer with the source, the drain and the substrate of the PMOS transistor as well.

FIG. 8 is a schematic diagram showing the area shared between the Poly resistor and the NMOS transistor. FIG. 8 only schematically shows the position relationship between the Poly resistor and the NMOS resistor. Actually, the Poly resistor and the NMOS resistor are not located in the same plane, and the Poly resistor is located above the NMOS resistor.

The area shared structure between the Poly resistor and the NMOS resistor operated in a linear area is further described by taking two specific application circuits as an example hereafter.

Referring to FIG. 3 again, another difference between the bias current generation circuit shown in FIG. 3 and the conventional bias current generation circuit is that a resistor R3 and a transistor MNst3 adopt an area sharing structure between the Poly resistor and the transistor.

The bias current generation circuit shown in FIG. 3 comprises a startup circuit provided for solving a problem of deadlocking in a zero current status of the bias current generation circuit. The startup circuit consists of transistors MPst1, MPst2, MNst3 and MNst4.

In order to reduce a static power consumption of the startup circuit, a resistance between a ST node and the ground should be big enough. The resistance of the NMOS transistor operated in the linear area is related with the width-to-length ratio of the NMOS transistor. The smaller the width-to-length ratio of the NMOS transistor is, and the bigger the resistance of the NMOS transistor is. The snakelike NMOS transistor with an inverse width-to-length ratio as shown in FIG. 7 is used as the transistor MNst3 because the snakelike NMOS transistor with the inverse width-to-length ratio has bigger resistance. The inverse width-to-length ratio means that the ratio of the width to the length of an active area of the NMOS transistor is far less than 1.

In order to further increase the resistance between the ST node and the ground, the resistor R3 is connected with the transistor NMOS transistor in series. The Poly resistor locating in different layer with the NMOS transistor is used as the resistor R3. The resistor R3 shares the area with the transistor NMst3 to reduce the chip area.

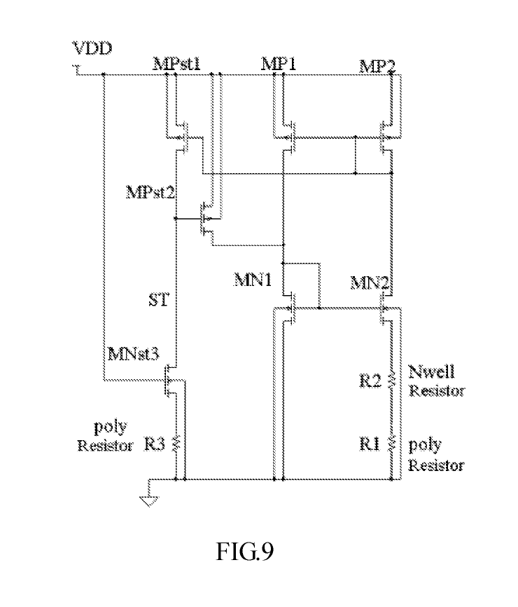

FIG. 9 is a circuit diagram showing another bias current generation circuit. The bias current generation circuit shown in FIG. 9 is obtained by improving the bias current generation circuit shown in FIG. 3. One difference between the bias current generation circuit shown in FIG. 3 and the bias current generation circuit shown in FIG. 9 is that the resistor R3 is connected to a drain of the transistor MNst3 in FIG. 3 and the resistor R3 is connected to a source of the transistor MNst3 in FIG. 9. The transistor MNst3 shown in FIG. 9 has smaller area than that shown in FIG. 3 when the resistance between the ST node and the ground shown in FIG. 3 is identical with that shown in FIG. 9. The principle is explained in detail hereafter.

The resistance of the NMOS transistor operated in the linear area is:

$$R = \frac{1}{μ \cdot {C}_{OX} \cdot \frac{W}{L} \cdot \vert {V}_{GS} - {V}_{TH} \vert}$$

Wherein V_{TH} is a threshold voltage, μ is a migration rate, C_{OX} is a trioxide capacitance on a unit area. V_{TH}, μ, C_{OX} is constant. Thus, the resistance of the NMOS transistor is only related to the width-to-length ratio W/L of the NMOS transistor and the voltage difference V.sub.GS between the gate and the source of the NMOS transistor. In FIG. 9, a voltage of the gate of the transistor MNst3 keeps unchanged and a voltage of the source of the transistor MNst3 is increased by connecting the resistor R3 to the source of the NMOS transistor MNst3. Thus, the voltage difference V.sub.GS between the gate and the source of the NMOS transistor MNst3 shown in FIG. 9 is smaller than that shown in FIG. 3. Hence, the NMOS transistor MNst3 shown in FIG. 9 has smaller area than that shown in FIG. 3 when the resistance between the ST node and the ground shown in FIG. 3 is identical with that shown in FIG. 9.

IV. Area Shared Between the Nwell Resistor and the NMOS Transistor in Specific Condition; Area Shared Between the Pwell Resistor and the PMOS Transistor in Specific Condition

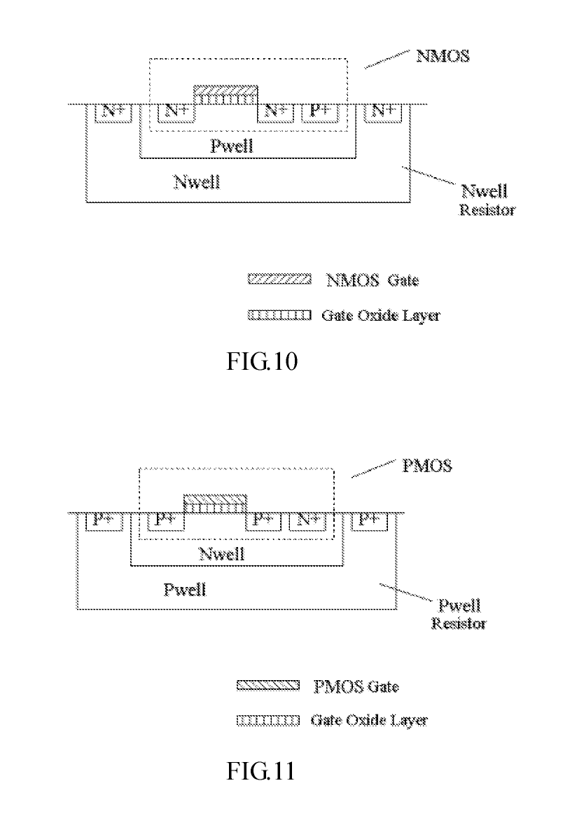

FIG. 10 is a sectional view showing the area sharing of the Nwell resistor and the NMOS resistor. Referring to FIG. 10, the upper device is the NMOS transistor and the lower device is the Nwell resistor, wherein N+ areas in the NMOS transistor are active areas of the NMOS transistor, and N+ areas in the Nwell resistor are connection terminals of the Nwell resistor. The Pwell area of the NMOS transistor is nonconductive with the Nwell resistor when a highest potential of the Pwell area of the NMOS transistor is lower than a lowest potential of the Nwell resistor. Hence, the Nwell resistor can share an area with the NMOS transistor in this specific condition.

FIG. 11 is a sectional view showing the area sharing of the Pwell resistor and the PMOS resistor. Referring to FIG. 11, the upper device is the PMOS transistor and the lower device is the Pwell resistor, wherein P+ areas in the PMOS transistor are active areas of the PMOS transistor, and P+ areas in the Pwell resistor are connection terminals of the Pwell resistor. The Nwell area of the PMOS transistor is nonconductive with the Pwell resistor when a highest potential of the Pwell resistor is lower than a lowest potential of the Nwell area of the PMOS transistor. Hence, the Pwell resistor can share an area with the PMOS transistor in this specific condition.

V. Area Shared Between the Poly Resistor and the Bipolar Transistor

The bipolar transistor comprises a PNP bipolar transistor and an NPN bipolar transistor. The P type areas of the PNP bipolar transistor and the NPN bipolar transistor are mainly formed by P+ and Pwell. The N type areas of the PNP bipolar transistor and the NPN bipolar transistor are mainly formed by N+ and Nwell. The Poly resistor isn't located in the same layer with the P+, Pwell, N+ and Nwell. Therefore, the Poly resistor can share an area with the bipolar transistor.

VI. Area Shared Between the NMOS Transistor and the PNP Bipolar Transistor in Specific Condition; Area Shared Between the PMOS Transistor and the NPN Bipolar Transistor in Specific Condition

FIG. 12 is a sectional view showing the area sharing of the NMOS transistor and the PNP bipolar transistor. Two N+ areas form a source and a drain of the NMOS transistor respectively, P+ area forms a substrate of the NMOS transistor, and Pwell is a P type area with lower concentration between the two N+ areas of the NMOS transistor. The Pwell, the Nwell and the P-sub form the PNP bipolar transistor. The Pwell is used as an emitter of the PNP bipolar transistor simultaneously, the Nwell is used as a base of the PNP bipolar transistor, and the P-sub is used as a collector electrode of the PNP bipolar transistor. The NMOS transistor can share an area with the PNP bipolar transistor when a highest potential of the Pwell of the PNP bipolar transistor is lower than a lowest potential of the N+ areas of the NMOS transistor.

Based on the same reason, the NMOS transistor can share an area with the NPN bipolar transistor when a highest potential of the Pwell of the NMOS transistor is lower than a lowest potential of the Nwell of the NPN bipolar transistor.

FIG. 13 is a sectional view showing the area sharing of the PMOS transistor and the NPN bipolar transistor. Two P+ areas form a source and a drain of the PMOS transistor respectively, N+ area forms a substrate contact region of the PMOS transistor, and Nwell forms a substrate of the PMOS transistor, which is an N type area with lower concentration between the two P+ areas of the PMOS transistor. The Nwell, the Pwell and the N-sub form the NPN bipolar transistor. The Nwell is used as an emitter of the NPN bipolar transistor simultaneously, the Pwell is used as a base of the NPN bipolar transistor, and the N-sub is used as a collector electrode of the NPN bipolar transistor. The PMOS transistor can share an area with the NPN bipolar transistor when a highest potential of the P+ areas of the PMOS transistor is lower than a lowest potential of the Nwell of the NPN bipolar transistor.

Based on the same reason, the PMOS transistor can share an area with the PNP bipolar transistor when a highest potential of the Pwell of the PNP bipolar transistor is lower than a lowest potential of the Nwell of the PMOS transistor.

VII. Area Shared Between the Trimming Circuit and Other Devices

The common trimming circuit comprises at least one trimming unit formed by a metal fuse, a polysilicon fuse or Zener diode. Specifically, a trimming circuit of a common reference voltage source requires five trimming units to meet commercial standard. Thus, a lot of chip area is occupied by the trimming circuit.

The trimming circuit and the metal resistor are located in the same layer which is the highest layer. Hence, the trimming circuit can't share an area with the metal resistor. However, the trimming circuit or the metal resistor can share an area with any other devices, such as a capacitor, the Poly resistor, the Nwell resistor, the NMOS transistor, the PMOS transistor, the NPN bipolar transistor, the PNP bipolar transistor and so on. Therefore, the area shared between the trimming circuit occupying a larger chip area and other devices can save the chip area significantly.

The area shared between the trimming circuit and other devices of the integrated circuit is described by taking the area shared between the trimming circuit and the capacitor as an example hereafter.

The capacitor generally occupies a bigger chip area and has simple connection. Hence, the capacitor is very suitable for being located below the trimming unit. Furthermore, the capacitor is even and has small effect on the evenness of the trimming unit. The capacitor sharing the area with the trimming circuit may be a polysilicon capacitor formed by two layers of polysilicon and may also be an MOS capacitor.

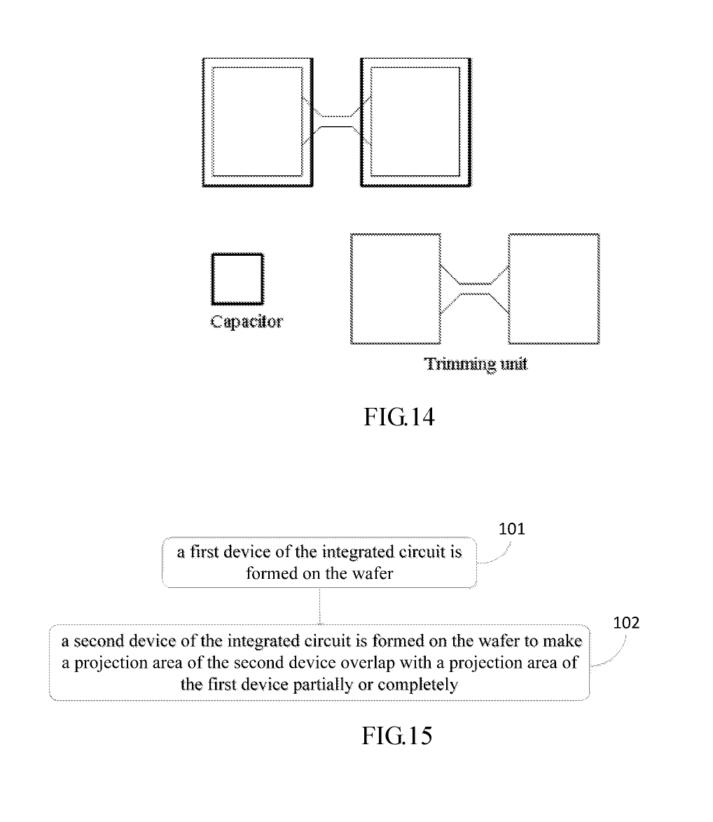

FIG. 14 is a schematic diagram showing the area shared between the trimming unit and the capacitor. The trimming circuit generally requires five trimming units. FIG. 14 only schematically shows the position relationship between the trimming unit and the capacitor. Moreover, the trimming unit and the capacitor in FIG. 14 are not in the same plane, and the trimming unit is located above the capacitor. Thus, the trimming unit can share an area with the capacitor to reduce the chip area.

In conclusion, the devices in different layers can share an area, and the devices in the same layer but at different depths can also share an area. Furthermore, a plurality of layers can share an area simultaneously. The more shared layers can reduce more area occupied by the chip.

It should be noted that: the area shared between the devices mentioned above may be interpreted into mutual overlapping of the projections of the devices on the same wafer. The term of “overlapping of the projections” doesn't means that the projections of each part of the devices on the same wafer overlap with each other, but means that the projections of the devices on the same wafer have overlapping area or the projections of the devices as a whole on the same wafer overlap with each other. For example, the Poly resistor and the Nwell resistor described above are placed in segments, and the Poly resistor segments are located between two adjacent Nwell resistor segments. The projection of each single Poly resistor segment on the same wafer doesn't overlap with the projection of each single Nwell resistor segment on the same wafer. However, the Poly resistor and the Nwell resistor both consist of plurality of resistor segments, thus the projection of the Poly resistor as a whole overlaps with the projection of the Nwell resistor as a whole.

Embodiments of a method for manufacturing an integrated circuit provided by the present invention are discussed herein with reference to FIGS. 15-18. However, those skilled in the art will readily appreciate that the detailed description given herein with respect to these figures is for explanatory purposes only as the invention extends beyond these embodiments.

FIG. 15 is a flow chart of a method for manufacturing an integrated circuit provided in an embodiment of the present invention. As shown in FIG. 15, the method includes:

Step 101: a first device of the integrated circuit is formed on the wafer;

Step 102: a second device of the integrated circuit is formed on the wafer to make a projection area of the second device overlap with a projection area of the first device partially or completely.

In this way, mutual overlapping of the projections of two or more devices formed on the same wafer may share an area by a certain manner. Thereby, the area of the chip is saved and the chip cost of the integrated circuit is reduced significantly.

In an embodiment of the present invention, as described before, an integrated circuit may consist of one to five layers, and each layer of the integrated circuit may consist of at least one area. Specifically, any one or any combination of an N+ resistor area, a P+ resistor area, an Nwell resistor area, a Pwell resistor area, an N+ area and a P+ area of a MOS transistor (e.g. an NMOS transistor or a PMOS transistor) and a bipolar transistor (e.g. an NPN bipolar transistor or a PNP bipolar transistor) area may be formed on a first layer which is the lowest layer; a Poly area of a gate of the MOS transistor may be formed on a second layer above the first layer; a Poly resistor area may be formed on a third layer above the second layer; any one or combination of a capacitor area and an inductor area may be formed on a fourth layer above the third layer; and any one or combination of a trimming circuit and a metal resistor may be formed on an uppermost fifth layer. Either of the first device and the second device may include at least one area or areas in the above five layers.

For example, devices such as the N+ resistor, the P+ resistor, the Nwell resistor, the Pwell resistor, the Poly resistor, the trimming circuit, the metal resistor and so on, are located in one layer of the integrated circuit. The MOS transistor is located in two layers of the integrated circuit. The Poly area of the MOS transistor is in the second layer of the integrated circuit, and the N+ area and P+ area of the MOS transistor are located in the first layer of the integrated circuit.

At this situation, if the first device and the second device are located in different layers, the first device and the second device can share an area when their projection areas overlap partially or completely.

In an embodiment of the present invention, the first device is one of an N+ resistor, a P+ resistor, an Nwell resistor, a Pwell resistor, a MOS transistor and a bipolar transistor, and the second device is a Poly resistor. As above described, the N+ resistor, the P+ resistor, the Nwell resistor, the Pwell resistor and the bipolar transistor are formed in the first layer, and the MOS transistor is formed in the first layer and the second layer, however the Poly resistor is formed on the third layer. Therefore, the first device and the second device can directly share a vertical area on the wafer to save the chip horizontal area.

In another embodiment, the first device is one of a capacitor, a Poly resistor, a Pwell resistor, an Nwell resistor, a MOS transistor and a bipolar transistor, and the second device is a trimming circuit or a metal resistor. As above described, the capacitor is formed on the fourth layer, the Poly resistor is formed on the third layer, the Nwell resistor, the Pwell resistor and the bipolar transistor are formed on the first layer, and the MOS transistor is formed on the first and the second layers, however the trimming circuit or the metal resistor is formed on an uppermost fifth layer. Therefore, the first device and the second device can directly share an area on the wafer to save the chip horizontal area.

Actually, the area shared is not limited to the above resistors. Any two or more resistors in different layers can share an area to save the chip horizontal area.

However, if an area of the second device and an area of the first device are formed at the same layer, the area of the second device may be conductive with the area of the first device, then the first device and the second device cannot work independently.

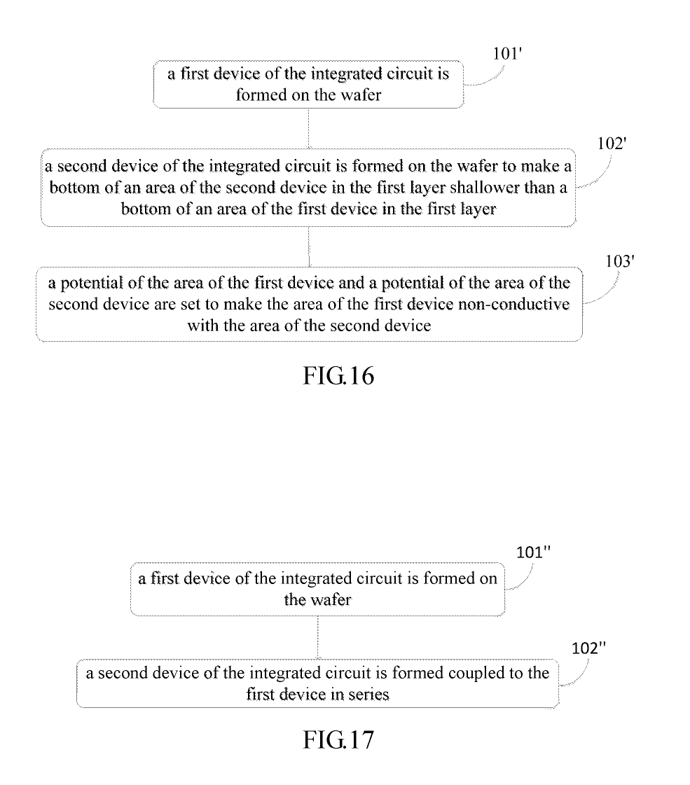

In an embodiment of the present invention, an integrated circuit comprises the first layer and the second layer, and the first device and the second device comprise at least one area in the first layer. FIG. 16 is a flow chart of a method for manufacturing an integrated circuit provided in this embodiment. As shown in FIG. 16, the method includes:

Step 101′: a first device of the integrated circuit is formed on the wafer;

Step 102′: a second device of the integrated circuit is formed on the wafer to make a bottom of an area of the second device in the first layer shallower than a bottom of an area of the first device in the first layer;

Step 103′: a potential of the area of the first device and a potential of the area of the second device are set to make the area of the first device non-conductive with the area of the second device.

By the potential setting process, the area of the first device is non-conductive with the area of the second device, so that the first device and the second device not only can share an area, but also can work independently.

In an embodiment, the first device is an Nwell resistor, and the second device is a Pwell resistor or P+ resistor. As shown in FIG. 4, the bottom of the P+ resistor is shallower than the bottom of the Nwell resistor. In other words, the Nwell resistor is deeper than the P+ resistor, in addition, the Nwell resistor is also deeper than the Pwell resistor. The P+ resistor/the Pwell resistor and the Nwell resistor are formed at different depths in the first layer, so they can share an area and work independently by setting a highest potential of the Pwell resistor/the P+ resistor lower than a lowest potential of the Nwell resistor.

In an embodiment of the present invention, the first device is an Nwell resistor, and the second device is an NMOS transistor. Referring to FIG. 10, the upper device is the NMOS transistor and the lower device is the Nwell resistor. N+ areas in the Nwell resistor are connection terminals of the Nwell resistor, N+ areas in the NMOS transistor are active areas of the NMOS transistor. A Pwell area is used as a substrate of the NMOS transistor and the bottom of the Pwell area is shallower than the bottom of the Nwell resistor. In other words, the Pwell area of the NMOS and the Nwell resistor are formed at different depths in the first layer. Hence, the Nwell resistor and the NMOS transistor can share an area and can work independently by setting a highest potential of the Pwell area of the NMOS transistor lower than a lowest potential of the Nwell resistor.

In another embodiment of the present invention, the first device is a Pwell resistor, and the second device is a PMOS transistor. Referring to FIG. 11, the upper device is the PMOS transistor and the lower device is the Pwell resistor. P+ areas in the Pwell resistor are connection terminals of the Pwell resistor, P+ areas in the PMOS transistor are active areas of the PMOS transistor. An Nwell area is used as a substrate of the PMOS transistor and the bottom of the Nwell area is shallower than the bottom of the Pwell resistor. In other words, the Nwell area of the PMOS and the Pwell resistor are formed at different depths in the first layer. Hence, the Pwell resistor and the PMOS transistor can share an area and can work independently by setting a highest potential of the Pwell resistor lower than a lowest potential of the Nwell area of the PMOS transistor.

In an embodiment, the first device is a PNP bipolar transistor, and the second device is an NMOS transistor. Referring to FIG. 12, two N+ areas form as a source and a drain of the NMOS transistor respectively. An Nwell is used as a base of the PNP bipolar transistor and a P-sub is used as a collector electrode of the PNP bipolar transistor. A Pwell area is used to form a substrate of the NMOS transistor, also used as an emitter of the PNP bipolar transistor simultaneously. The bottom of the two N+ areas of the NMOS transistor is shallower than the bottom of the Pwell area of the PNP bipolar transistor. In other words, the two N+ areas of the NMOS transistor and the Pwell area of the PNP bipolar transistor are formed at different depths in the first layer. Hence, the NMOS transistor and the PNP bipolar transistor can share an area and can work independently by setting a highest potential of the Pwell area of the PNP bipolar transistor lower than a lowest potential of the two N+ areas of the NMOS transistor. It can be seen that not only a horizontal area is saved but also a vertical area for the chip is saved in this way.

In another embodiment, the first device is an NPN bipolar transistor, and the second device is a PMOS transistor. Referring to FIG. 13, two P+ areas form as a source and a drain of the PMOS transistor respectively. A Pwell is used as a base of the NPN bipolar transistor and an N-sub is used as a collector electrode of the NPN bipolar transistor. An Nwell area is used to form a substrate of the PMOS transistor, also used as an emitter of the NPN bipolar transistor simultaneously. The bottom of the two P+ areas of the PMOS transistor is shallower than the bottom of the Nwell area of the NPN bipolar transistor. In other words, the two P+ areas of the PMOS transistor and the Nwell area of the NPN bipolar transistor are formed at different depths in the first layer. Hence, the PMOS transistor and the NPN bipolar transistor can share an area and can work independently by setting a highest potential of the two P+ areas of the PMOS transistor lower than a lowest potential of the Nwell area of the NPN bipolar transistor. It can also be seen that not only a horizontal area is saved but also a vertical area for the chip is saved in this way.

FIG. 17 is a flow chart of a method for manufacturing an integrated circuit provided in another embodiment of the present invention. As shown in FIG. 17, the method includes:

Step 101″: a first device of the integrated circuit is formed on the wafer;

Step 102″: a second device of the integrated circuit is formed coupled to the first device in series.

In an embodiment, the first device is a NMOS transistor, the second device is a Poly resistor, and the Poly resistor is formed coupled to a source of the NMOS transistor (as shown in FIG. 9).

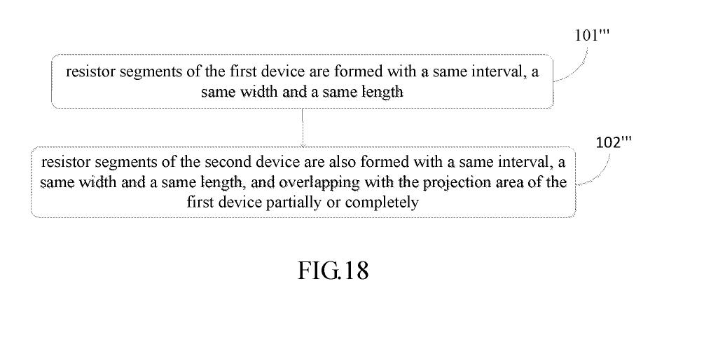

FIG. 18 is a flow chart of a method for manufacturing an integrated circuit provided in another embodiment of the present invention. In this embodiment, both of a first device and a second device are resistors consisting of resistor segments, and the method includes:

Step 101′″: resistor segments of the first device are formed with a same interval, a same width and a same length;

Step 102′″: resistor segments of the second device are also formed with a same interval, a same width and a same length, and overlapping with the projection area of the first device partially or completely.

The matching degree of the resistors will be improved when the same type of the resistor is placed in segments orderly and keep the same interval between the segments.

In a preferred embodiment, each resistor segment of the second device is formed between two adjacent resistor segments of the first device, and an extension direction of the resistor segments of the second device is identical with an extension direction of the resistor segments of the first device.

In this way, the matching degree between the first device and the second device can be improved. Moreover, when the extension direction of the resistor segments of the second device is identical with the extension direction of the resistor segments of the first device, the matching degree between the two devices will be further improved, and the space and the chip area will be further saved.

The present invention has been described in sufficient details with a certain degree of particularity. It is understood to those skilled in the art that the present disclosure of embodiments has been made by way of examples only and that numerous changes in the arrangement and combination of parts may be resorted without departing from the spirit and scope of the invention as claimed. Accordingly, the scope of the present invention is defined by the appended claims rather than the foregoing description of embodiments.

1. A method for manufacturing an integrated circuit on a wafer, comprising:
forming a first device of the integrated circuit on the wafer; and
forming a second device of the integrated circuit on the wafer to make a projection area of the second device overlap with a projection area of the first device partially or completely.

2. The method according to claim 1, wherein the first device is one of an N+ resistor, a P+ resistor, an Nwell resistor, a Pwell resistor, a MOS transistor and a bipolar transistor, and the second device is a Poly resistor.

3. The method according to claim 1, wherein the first device is one of a capacitor, a Poly resistor, a Pwell resistor, an Nwell resistor, a MOS transistor and a bipolar transistor, and the second device is a trimming circuit or a metal resistor.

4. The method according to claim 1, wherein the integrated circuit comprises:
a first layer, comprising any one or any combination of an N+ resistor area, a P+ resistor area, an Nwell resistor area, a Pwell resistor area, an N+ area of a MOS transistor, a P+ area of a MOS transistor and a bipolar transistor area; and
a second layer, prepared above the first layer and comprising a Poly area of a gate of a MOS transistor,
wherein either of the first device and the second device comprises at least one area in the first layer.

5. The method according to claim 4, wherein forming a second device of the integrated circuit on the wafer to make a projection area of the second device overlap with a projection area of the first device partially or completely comprises:
forming the second device of the integrated circuit on the wafer to make a bottom of an area of the second device in the first layer shallower than a bottom of an area of the first device in the first layer;
wherein the method further comprises:
setting a potential of the area of the first device and a potential of the area of the second device to make the area of the first device non-conductive with the area of the second device.

6. The method according to claim 5, wherein the first device is an Nwell resistor, and the second device is a Pwell resistor or a P+ resistor,
wherein forming the second device of the integrated circuit on the wafer to make a bottom of an area of the second device in the first layer shallower than a bottom of an area of the first device in the first layer comprises:
forming the second device of the integrated circuit on the wafer to make the bottom of the second device shallower than the bottom of the first device;
wherein setting a potential of the area of the first device and a potential of the area of the second device to make the area of the first device non-conductive with the area of the second device comprises:
setting a highest potential of the second device lower than a lowest potential of the first device.

7. The method according to claim 5, wherein the first device is an Nwell resistor, and the second device is an NMOS resistor,
wherein forming the second device of the integrated circuit on the wafer to make a bottom of an area of the second device in the first layer shallower than a bottom of an area of the first device in the first layer comprises:
forming the second device of the integrated circuit on the wafer to make the bottom of a Pwell area of the second device shallower than the bottom of the first device;
wherein setting a potential of the area of the first device and a potential of the area of the second device to make the area of the first device non-conductive with the area of the second device comprises:
setting a highest potential of the Pwell area of the second device lower than a lowest potential of the first device.

8. The method according to claim 5, wherein the first device is a Pwell resistor, and the second device is a PMOS transistor,
wherein forming the second device of the integrated circuit on the wafer to make a bottom of an area of the second device in the first layer shallower than a bottom of an area of the first device in the first layer comprises:
forming the second device of the integrated circuit on the wafer to make the bottom of a Nwell area of the second device shallower than the bottom of the first device;
wherein setting a potential of the area of the first device and a potential of the area of the second device to make the area of the first device non-conductive with the area of the second device comprises:
setting a highest potential of the first device lower than a lowest potential of the Nwell area of the second device.

9. The method according to claim 5, wherein the first device is a PNP bipolar transistor, and the second device is an NMOS transistor,
wherein forming the second device of the integrated circuit on the wafer to make a bottom of an area of the second device in the first layer shallower than a bottom of an area of the first device in the first layer comprises:
forming the second device of the integrated circuit on the wafer to make the bottom of two N+ areas of the second device shallower than the bottom of a Pwell area of the first device, wherein the Pwell area is used as an emitter of the first device and used as a substrate of the second device;
wherein setting a potential of the area of the first device and a potential of the area of the second device to make the area of the first device non-conductive with the area of the second device comprises:
setting a highest potential of the Pwell area of the first device lower than a lowest potential of the two N+ areas of the second device.

10. The method according to claim 5, wherein the first device is an NPN bipolar transistor, and the second device is a PMOS transistor,
wherein forming the second device of the integrated circuit on the wafer to make a bottom of an area of the second device in the first layer shallower than a bottom of an area of the first device in the first layer comprises:
forming the second device of the integrated circuit on the wafer to make the bottom of two P+ areas of the second device shallower than the bottom of a Nwell area of the first device, wherein the Nwell area is used as an emitter of the first device and used as a substrate of the second device;
wherein setting a potential of the area of the first device and a potential of the area of the second device to make the area of the first device non-conductive with the area of the second device comprises:
setting a highest potential of the two P+ areas of the second device lower than a lowest potential of the Nwell area of the first device.

11. The method according to claim 1, wherein forming a second device of the integrated circuit on the wafer to make a projection area of the second device overlap with a projection area of the first device partially or completely comprises:
forming the second device coupled to the first device in series.

12. The method according to claim 11, wherein the first device is a NMOS transistor, and the second device is a Poly resistor,
wherein forming the second device coupled to the first device in series comprises:
forming the Poly resistor coupled to a source of the NMOS transistor.

13. The method according to claim 1, wherein both of the first device and the second device are resistors,
wherein forming a first device of the integrated circuit on the wafer comprises:
forming resistor segments of the first device with a same interval, a same width and a same length;
wherein forming a second device of the integrated circuit on the wafer to make a projection area of the second device overlap with a projection area of the first device partially or completely comprises:
forming resistor segments of the second device, with a same interval, a same width and a same length, overlapping with the projection area of the first device partially or completely.

14. The method according to claim 13, wherein forming resistor segments of the second device with a same interval, a same width and a same length, overlapping with the projection area of the first device partially or completely comprises:
forming each resistor segment of the second device between two adjacent resistor segments of the first device, wherein an extension direction of the resistor segments of the second device is identical with an extension direction of the resistor segments of the first device.
